(19) United States
(12) Patent Application Publication
(10) Pub. No.: US 2011/0294287 A1
(43) Pub. Date: Dec. 1, 2011

(54) METHOD OF MANUFACTURING SEMICONDUCTOR DEVICE HAVING DUAL FULLY-SILICIDED GATE

(75) Inventors: Chin-Hsiang Lin, Hsinchu City (TW); Chia-Jung Hsu, Changhua County (TW); Li-Wei Cheng, Hsinchu City (TW); Hsien-Liang Meng, Hsinchu (TW); Ming-Te Wei, Changhua County (TW); Che-Hua Hsu, Hsinchu County (TW)

(73) Assignee: United Microelectronics Corp., Hsinchu (TW)

(21) Appl. No.: 13/208,772

(22) Filed: Aug. 12, 2011

Related U.S. Application Data
(62) Division of application No. 11/620,984, filed on Jan. 8, 2007.

(51) Int. Cl. H01L 21/263

(52) U.S. Cl. 438/591; 257/E21.333

(57) ABSTRACT

A method of manufacturing the semiconductor device having a dual fully-silicided gate includes the following steps. A substrate having a first transistor and a second transistor formed thereon is provided, wherein the first transistor includes a first gate and a first source/drain and the second transistor includes a second gate and a second source/drain. The gate height of the first gate is different from that of the second gate. A first silicidation process is performed to respectively transform the first gate and the second gate into a first silicided gate and a second silicided gate simultaneously, wherein the material of the first silicided gate is different from that of the second silicided gate.

### CROSS-REFERENCE TO RELATED APPLICATION

This application is a divisional application of and claims the priority benefit of U.S. application Ser. No. 11/620,984, filed on Jan. 8, 2007, now pending. The entirety of the above-mentioned patent application is hereby incorporated by reference herein and made a part of this specification.

### BACKGROUND OF THE INVENTION

1. Field of the Invention

The present invention relates to a method of manufacturing a semiconductor device. More particularly, the present invention relates to a method of manufacturing a semiconductor device having a dual fully-silicided gate.

2. Description of Related Art

With the increasing integration of integrated circuits, the dimension of semiconductor devices is gradually reduced accordingly. As the dimension of the metal oxide semiconductor (MOS) transistor is reduced, the channel length thereof must be reduced as well. However, the reduction of the channel size of the MOS transistor is limited. When the length is reduced to a certain extent, various problems resulting from the reduction in the channel length occur, namely short channel effect. The so-called short channel effect may cause a device threshold voltage (Vt) drop and poor control of the gate voltage (Vg) to the MOS transistor, and a punch-through effect also influences the operation of the MOS transistor. Particularly, when the size of the MOS transistor is reduced to the nanometer scale, the short channel effect and the punch-through effect become serious, such that the semiconductor device cannot be further reduced.

Generally, the material of the gate dielectric layer of the conventional MOS transistor is silicon oxide, and the material of the gate is polysilicon. For the gate dielectric layer, the problem of the above short channel effect can be overcome by reducing the thickness of the gate oxide layer and using a high-K material. However, the reduction in the thickness of the gate oxide layer incurs more serious polysilicon depletion, resulting in the reduction in the gate capacitance and decrease in the driving force. In another aspect, when a high-K material is employed serving as the gate dielectric layer, Fermi level pinning issue occurs when the polysilicon gate contacts the high-K material, thus easily causing a higher threshold voltage (Vt) then reduce the device operation current. Therefore, in order to use the high-K material serving as the gate dielectric layer, the gate need to be made of a metal material.

A dual metal gate process is usually employed in the manufacturing of the metal gate of complementary metal oxide semiconductor (CMOS) device. An N-channel metal oxide semiconductor (NMOS) device and a P-channel metal oxide semiconductor (PMOS) device are fabricated by using metal materials having different power functions, such that the NMOS and the PMOS have different threshold voltages and electrical characteristics.

Conventionally, U.S. Pat. No. 6,905,922 discloses a method of forming dual fully-silicided gate. In the U.S. Pat. No. 6,905,922, when performing silicidation reaction of the PMOS and the NMOS, one of the PMOS and NMOS is reacted first, and then the other PMOS and NMOS is reacted. As such, a lithographic etching process must be repeated several times to form the metal layer to cover only the PMOS or the NMOS. Therefore, the process is quite complicated, and the manufacturing cost cannot be reduced.

### SUMMARY OF THE INVENTION

An objective of the present invention is to provide a method of manufacturing a semiconductor device having a dual fully-silicided gate, which can be used to fabricate two kinds of metal gates having different characteristics in one silicidation process, thereby simplifying the process and reducing the manufacturing cost.

The present invention provides a method of manufacturing the semiconductor device having a dual fully-silicided gate, which includes the following steps. A substrate having a first transistor and a second transistor formed thereon is provided, wherein the first transistor includes a first gate and a first source/drain and the second transistor includes a second gate and a second source/drain. The gate height of the first gate is different from that of the second gate. A first silicidation process is performed to respectively transform the first gate and the second gate into a first silicided gate and a second silicided gate simultaneously, wherein the material of the first silicided gate is different from that of the second silicided gate.

According to an embodiment of the present invention, the material of the first gate includes undoped polysilicon, and the material of the second gate includes doped polysilicon.

According to an embodiment of the present invention, the gate height ratio of the first gate and the second gate is 1.4˜1.8.

According to an embodiment of the present invention, the material of the first silicided gate includes silicon-rich silicide, and the material of the second silicided gate includes metal-rich silicide.

According to an embodiment of the present invention, the gate silicide height ratio of the first gate silicide and the second gate silicide is 0.8˜1.5.

According to an embodiment of the present invention, the gate silicide height ratio of the first gate silicide and the second gate silicide is 1.0˜1.3.

According to an embodiment of the present invention, the material of the first silicided gate and the second silicided gate includes one of the refractory metal, noble metal, and rear-earth metal silicide.

According to an embodiment of the present invention, the first silicidation process includes the following steps. A first metal layer is formed on the substrate in contact with the first gate and the second gate. A first annealing process is performed, such that the first metal layer is reacted with the first gate and the second gate to form a silicide. Then, the unreacted first metal layer is removed. In some case, a second annealing process is performed to form a lower resistance silicide.

According to an embodiment of the present invention, the material of the first metal layer is selected from a group consisting of Ni, Co, Ti, Cu, Mo, Ta, W, Er, Zr, Pt, Yb, Gd, Dy and alloys thereof.

According to an embodiment of the present invention, the material of the first silicided gate includes silicon-rich NiSi (with the Ni/Si composition ratio of Ni:Si<1.5:1), and the material of the second silicided gate includes nickel-rich NiSi (with the Ni/Si composition ratio of Ni:Si>1.5:1).

According to an embodiment of the present invention, the silicon-rich silicide includes NiSi2 or NiSi.

According to an embodiment of the present invention, the nickel-rich silicide includes Ni2Si, Ni31Si12 or Ni3Si.

According to an embodiment of the present invention, before performing the first silicidation process, a material layer is formed on the substrate, and a portion of the material layer is removed to expose only the first gate and the second gate.

According to an embodiment of the present invention, the material layer includes a spin-coating material layer, and the material of the material layer includes silicon oxide, PSG, BPSG or low k material (dielectric constant is lower than 4).

According to an embodiment of the present invention, after performing the first silicidation process, the residual material layer is removed, and a second silicidation process is performed to form a silicided layer on the first source/drain and the second source/drain.

According to an embodiment of the present invention, the second silicidation process includes the following steps. A second metal layer is formed on the substrate in contact with the first source/drain and the second source/drain. A first annealing process is performed, such that the second metal layer is reacted with the first source/drain and the second source/drain to form a silicide. Then, the unreacted second metal layer is removed. In some case, a second annealing process is performed to form a lower resistance silicide.

According to an embodiment of the present invention, the material of the second metal layer is selected from a group consisting Ni, Co, Ti, Cu, Mo, Ta, W, Er, Zr, Pt, Yb, Gd, Dy and the alloy thereof.

According to an embodiment of the present invention, a process temperature of the second silicided layer is lower than that of the first silicided gate and the second silicided gate.

According to an embodiment of the present invention, a material of the second silicided layer is NiSi.

According to an embodiment of the present invention, a first gate dielectric layer is formed between the first gate and the substrate and a second gate dielectric layer is formed between the second gate and the substrate.

According to an embodiment of the present invention, the first gate dielectric layer and the second gate dielectric layer are respectively formed by one or more dielectric material layers. The first gate dielectric layer and the second gate dielectric layer are formed by the same material layers or the different material layers.

According to an embodiment of the present invention, the material of the first gate dielectric layer and the second gate dielectric layer includes a high-K material with a dielectric constant larger than 4.

According to an embodiment of the present invention, the material of the first gate dielectric layer and the second gate dielectric layer is selected from a group consisting SiO2, SiON, SiN, Ta2O5, Al2O3, HfO2, HfSiON, HfSiO2, and HfAlSiO2.

According to an embodiment of the present invention, the first transistor and the second transistor are FinFETs.

According to an embodiment of the present invention, the first transistor and the second transistor are Multi-gate transistors.

According to an embodiment of the present invention, only one silicidation process is required to form the first silicided gate and the second silicided gate having different properties, thus an additional lithographic etching process is not required, and the process is simplified.

Moreover, the material layer is used to protect the first source/drain and the second source/drain, so when performing the silicidation process to form the first silicided gate and the second silicided gate simultaneously, the first metal layer is prevented from being further reacted with silicon in the first source/drain and the second source/drain.

The present invention provides a method of manufacturing the semiconductor device having a dual fully-silicided gate, which includes the following steps. A substrate having a first transistor and a second transistor formed thereon is provided, wherein the first transistor includes a first gate, a first cap layer, and a first source/drain, and the second transistor includes a second gate, a second cap layer, and a second source/drain. The gate height of the first gate is different from that of the second gate. A first silicidation process is performed to form a silicided layer on the first source/drain and the second source/drain. The first cap layer and the second cap layer are removed. A second silicidation process is performed to respectively transform the first gate and the second gate into a first silicided gate and a second silicided gate simultaneously, wherein the material of the first silicided gate is different from that of the second silicided gate.

According to an embodiment of the present invention, the first silicidation process includes the following steps. A first metal layer is formed on the substrate in contact with the first source/drain and the second source/drain. A first annealing process is performed, such that the first metal layer is reacted with the first source/drain and the second source/drain to form a silicide. The unreacted first metal layer is removed. In some case, a second annealing process is performed to form a lower resistance silicide.

According to an embodiment of the present invention, the material of the first metal layer is selected from a group consisting of Ni, Co, Ti, Cu, Mo, Ta, W, Er, Zr, Pt, Yb, Gd, Dy and alloys thereof.

According to an embodiment of the present invention, the material of the first gate includes undoped polysilicon, and the material of the second gate includes doped polysilicon.

According to an embodiment of the present invention, the gate height ratio of the first gate and the second gate is 1.4˜1.8.

According to an embodiment of the present invention, the material of the first silicided gate includes silicon-rich silicide, and the material of the second silicided gate includes metal-rich silicide.

According to an embodiment of the present invention, the second silicidation process includes the following steps. A second metal layer is formed on the substrate in contact with the first gate and the second gate. A first annealing process is performed, such that the second metal layer is reacted with the first gate and the second gate to form a silicide. The unreacted second metal layer is removed. In some case, a second annealing process is performed to form a lower resistance silicide.

According to an embodiment of the present invention, the material of the second metal layer is selected from a group consisting of Ni, Co, Ti, Cu, Mo, Ta, W, Er, Zr, Pt, Yb, Gd, Dy and alloys thereof.

According to an embodiment of the present invention, the material of the first silicided gate includes silicon-rich metal silicide, for example, NiSi2 or NiSi (with the Ni/Si composition ratio of Ni:Si<1.5:1), and the material of the second silicided gate includes nickel-rich silicide, for example, Ni2Si, Ni31Sil2 or Ni3Si (with the Ni/Si composition ratio of Ni:Si>1.5:1).

According to an embodiment of the present invention, the process of removing the first cap layer and the second cap layer includes an etching process.

According to an embodiment of the present invention, after removing portions of the first cap layer and the second cap layer, a portion of the first gate or a portion of the second gate is removed.

According to an embodiment of the present invention, the process temperature of the silicided layer is higher than that of the first silicided gate and the second silicided gate.

According to an embodiment of the present invention, after performing the first silicidation process, a material layer is formed on the substrate, and portions of the material layer, the first cap layer and the second cap layer are removed until the first gate and the second gate are exposed.

According to an embodiment of the present invention, after removing portions of the material layer, the first cap layer and the second cap layer, a portion of the first gate or a portion of the second gate is removed.

According to an embodiment of the present invention, the process of removing portions of the material layer, the first cap layer and the second cap layer includes chemical mechanical polishing (CMP) or etching process.

According to an embodiment of the present invention, the etching process of removing portions of the material layer, the first cap layer and the second cap layer includes dry etching process or wet etching process.

According to an embodiment of the present invention, after performing the first silicidation process, a material layer and a insulation layer are formed on the substrate, and portions of the insulation layer, the material layer, the first cap layer and the second cap layer are removed until the first gate and the second gate are exposed.

According to an embodiment of the present invention, after removing portions of the insulation layer, the material layer, the first cap layer and the second cap layer, a portion of the first gate or a portion of the second gate is removed.

According to an embodiment of the present invention, the process of removing portions of the insulation layer, the material layer, the first cap layer and the second cap layer includes chemical mechanical polishing (CMP) or etching process.

According to an embodiment of the present invention, the first transistor includes an NMOS transistor or a PMOS transistor, and the second transistor includes an NMOS transistor or a PMOS transistor.

According to an embodiment of the present invention, a first gate dielectric layer is formed between the first gate and the substrate, and a second gate dielectric layer is formed between the second gate and the substrate.

According to an embodiment of the present invention, the first gate dielectric layer and the second gate dielectric layer are formed by one or more dielectric material layers.

According to an embodiment of the present invention, the material of the first gate dielectric layer and the second gate dielectric layer includes a high-K material with a dielectric constant larger than 4.

According to an embodiment of the present invention, the material of the first gate dielectric layer and the second gate dielectric layer is selected from a group consisting of SiO2, SiON, SiN, Ta2O5, Al2O3, HfO2, HfSiON, HfSiO2, and HfAlSiO2.

According to an embodiment of the present invention, the first transistor and the second transistor are FinFETs.

According to an embodiment of the present invention, the first transistor and the second transistor are Multi-gate transistors.

According to an embodiment of the present invention, the materials of the first gate and the second gate are different. After removing the first cap layer and the second cap layer to expose the first gate and the second gate, a silicidation process is performed to form the first silicided gate and the second silicided gate having different properties. The additional lithographic etching process is not required, thus simplifying the process. Moreover, if the etching process instead of CMP is used to remove the first cap layer and the second cap layer, the process can also be simplified, and the cost can be reduced.

Moreover, the process temperature of the source/drain silicided layer is higher than that of the first silicided gate and the second silicided gate, and when forming the first silicided gate and the second silicided gate, the second metal layer is prevented from further reacting with the first source/drain and the second source/drain, thereby avoid influencing the device characteristics.

Furthermore, the height of the first gate and the second gate can be adjusted by removing the exposed portion of the first gate and the second gate, so the first silicided gate and the second silicided gate subsequently formed can be adjusted, such that the first silicided gate and second silicided gate have preferred operation performance and characteristic.

In order to make the aforementioned and other objects, features and advantages of the present invention comprehensible, preferred embodiments accompanied with figures are described in detail below.

### BRIEF DESCRIPTION OF THE DRAWINGS

FIG. 1A to FIG. 1D are sectional views of the process steps of the method of manufacturing the semiconductor device having a dual fully-silicided gate according to a first embodiment of the present invention.

FIG. 2A to FIG. 2D are sectional views of the process steps of the method of manufacturing the semiconductor device having a dual fully-silicided gate according to a second embodiment of the present invention.

FIG. 3A to FIG. 3D are sectional views of the process steps of the method of manufacturing the semiconductor device having a dual fully-silicided gate according to a third embodiment of the present invention.

### DESCRIPTION OF EMBODIMENTS

### The First Embodiment

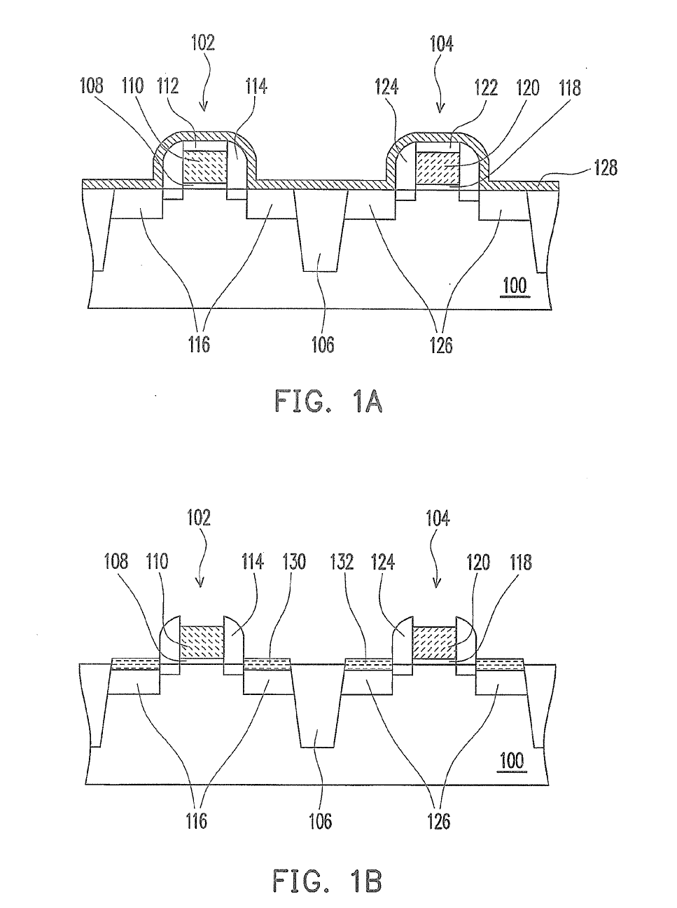

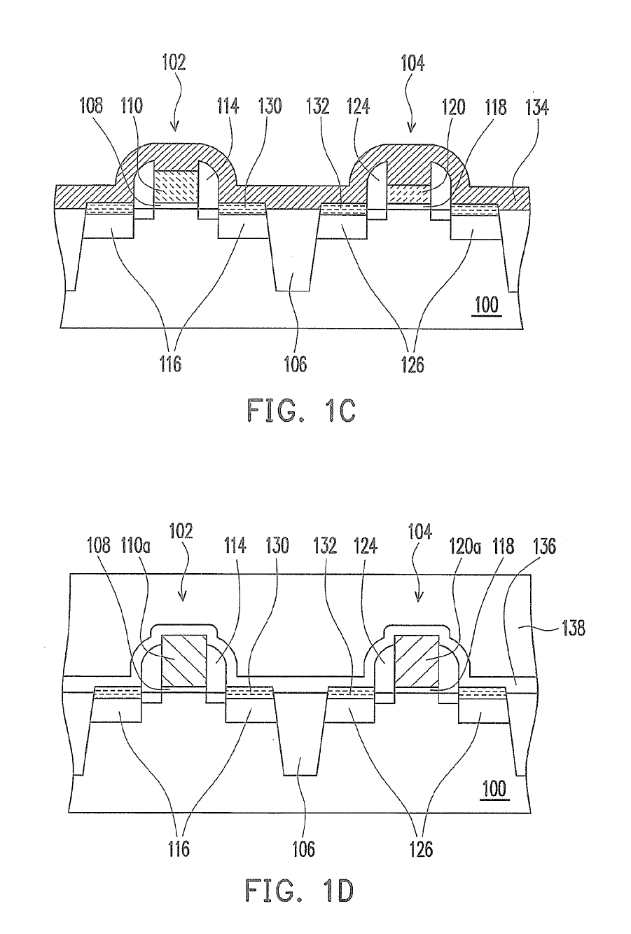

FIG. 1A to FIG. 1D are cross-sectional views of the process steps of the method of manufacturing the semiconductor device having a dual fully-silicided gate according to the first embodiment of the present invention.

Referring to FIG. 1A, first a substrate 100 is provided. The substrate 100 includes a silicon substrate, for example, an N-type silicon substrate or a P-type silicon substrate. The substrate 100 can be a silicon-on-insulating layer substrate and the like.

A transistor 102 and a transistor 104 are already formed on the substrate 100. The transistor 102 and the transistor 104 are isolated by, for example, device isolation structures 106. The device isolation structure 106 is, for example, a shallow trench isolation structure or a field oxide layer.

The transistor 102 includes, for example, a gate dielectric layer 108, a gate 110, a cap layer 112, spacers 114, and source/drain 116.

The gate dielectric layer 108 is disposed between the gate 110 and the substrate 100. The material of the gate dielectric layer includes a high-K material with a dielectric constant larger than 4, such as SiO2, SiON, SiN, Ta2O5, Al2O3, HfO2, HfSiON, HfSiO2, and HfAlSiO2. The gate dielectric layer 108 is formed by one or more dielectric material layers. For example, the gate dielectric layer 108 can be formed by a single layer of the above high-K material, or formed by a silicon oxide layer and a high-K material layer.

The cap layer 112 is, for example, disposed on the gate 110. The material of the cap layer 112 is, for example, silicon oxide or silicon nitride or silicon oxy-nitride. The spacers 114 are, for example, disposed on the sidewalls of the gate 110. The material of the spacers 114 are, for example, silicon oxide or silicon nitride or their compositions. The source/drains 116 are, for example, disposed in the substrate on both sides of the gate 110.

The material of the gate 110 includes silicon based material, for example, selected from a group consisting of doped silicon, undoped silicon, doped polysilicon, and undoped polysilicon. When the material of the gate 110 is doped silicon or doped polysilicon, the dopant in the silicon or polysilicon can be N-type dopant or P-type dopant. The transistor 102 is, for example, an N-channel metal oxide semiconductor (NMOS) device or a P-channel metal oxide semiconductor (PMOS) device. In the first embodiment, the material of the gate 110 is, for example, undoped polysilicon and the transistor 102 is, for example, NMOS in the following description.

The transistor 104 includes, for example, a gate dielectric layer 118, a gate 120, a cap layer 122, spacers 124, and source/drain 126.

The gate dielectric layer 118 is disposed between the gate 120 and the substrate 100. The material of the gate dielectric layer 118 includes a high-K material with a dielectric constant larger than 4, such as SiO2, SiON, SiN, Ta2O5, Al2O3, HfO2, HfSiON, HfSiO2, and HfAlSiO2. The gate dielectric layer 118 is formed by one or more dielectric material layers. For example, the gate dielectric layer 118 can be formed by a single layer of the above high-K material, or formed by a silicon oxide layer and a high-K material layer.

The cap layer 122 is, for example, disposed on the gate 120. The material of the cap layer 122 is, for example, silicon oxide or silicon nitride or silicon oxy-nitride. The spacers 124 are, for example, disposed on the sidewalls of the gate 120. The material of the spacers 124 are, for example, silicon oxide or silicon nitride or their compositions. The source/drains 126 are, for example, disposed in the substrate on both sides of the gate 120.

The material of the gate 120 includes silicon based material, for example, selected from a group consisting of doped silicon, undoped silicon, doped polysilicon, and undoped polysilicon. When the material of the gate 120 is doped silicon or doped polysilicon, the dopant in the silicon or polysilicon can be N-type dopant or P-type dopant. The transistor 104 is, for example, an NMOS or a PMOS. In the following description, the material of the gate 120 is, for example, doped polysilicon, and the transistor 104 is, for example, a PMOS.

The transistor 102 and the transistor 104 on the substrate 100 may be fabricated by using a common complementary MOS process, and the details will not be described herein.

Next, a metal layer 128 is formed on the substrate 100. The material of the metal layer 128 includes one of the refractory metal, noble metal, and rear-earth metal, for example, selected from a group consisting of Ni, Co, Ti, Cu, Mo, Ta, W, Er, Zr, Pt, Yb, Gd, Dy and alloys thereof. The method of forming the metal layer 128 includes evaporation, sputtering, electroplating, chemical vapor deposition (CVD), or physical vapor deposition (PVD). In the following description, the material of the metal layer 128 includes, for example, Co.

Referring to FIG. 1B, a first annealing process is performed, such that the silicon in the source/drain 116 and the source/drain 126 is reacted with the metal layer 128 to form transition silicided layers (not shown) During the first annealing process, the metal layer 128 and the silicon layer adjacent to the metal layer 128 assume a inter-diffusion state due to high temperature, and the atoms are rearranged to form transition silicides. The formed transition silicides include one of the refractory metal, noble metal and rear-earth metal silicide, for example, selected from a group of silicides of metals Ni, Co, Ti, Cu, Mo, Ta, W, Er, Zr, Pt, Yb, Gd, Dy and alloys thereof. In the embodiment of this present invention, the material of transition silicides includes, for example, CoSi.

The temperature of the first annealing process and the time of the annealing process vary in accordance with different materials of the metal layer. In the present embodiment, the material of the metal layer 128 is, for example, Co, and the temperature of the first annealing process is, for example, 400˜800° C., and the annealing time is about 10˜360 seconds.

Next, the unreacted metal layer 128 is removed. In the present invention, the so-called unreacted metal layer 128 refers to a part of the metal layer 128 which does not participate in the silicidation reaction or is not completely reacted. The method of removing the unreacted metal layer 128 is, for example, a selective wet-etching process. The unreacted metal layer 128 is removed by using a hydrochloric acid/hydrogen peroxide mixed solution or a sulfuric acid/hydrogen peroxide mixed solution as etchant, only leaving the transition silicided layers on the surface of the source/drain 116 and the source/drain 126. A second annealing process with the higher temperature is performed to transfer the source/drain 116 and source/drain 126 transition silicided layers to the lower resistance silicided layers 130, 132. In the present embodiment, the material of the transition silicided layers are, for example, CoSi, and the temperature of the second annealing process is, for example, 500˜900° C., and the annealing time is about 30˜360 seconds. The lower resistance silicided layers 130, 132, for example, are CoSi2. In the present invention, the so-called silicidation process includes a metal layer forming process, a first annealing process, a process of removing the unreacted metal layer, and a second annealing process.

Next, the cap layers 112, 122 are removed to expose the gates 110, 120. The method of removing the cap layers 112, 122 is, for example, wet-etching. The etchant used in the wet-etching process depends on the material of the cap layers 112, 122. For example, when the material of the cap layers 112, 122 is silicon oxide, a hydrofluoric acid solution is used as the etchant, and when the material of the cap layers 112, 122 is silicon nitride, a hot phosphoric acid solution is used as the etchant.

Referring to FIG. 1C, the exposed portions of the gates 110, 120 are removed, so as to adjust the heights of the gates 110, 120. Since the materials of the gate 110 and the gate 120 are different, the etching selectivities are different. In the present embodiment, the material of the gate 110 is undoped polysilicon, and the material of the gate 120 is doped polysilicon. The method of removing a part of the gates 110, 120 includes an etching process, for example, a dry etching process or a wet etching process. When removing a part of the gates 110, 120 with the dry etching process, the mixed gas of chlorine gas (or bromine gas) and hexafluoroethane serves as the reaction gas. In this circumstance, the etching rate of the doped polysilicon is larger than that of the undoped polysilicon. Therefore, the height of the gate 110 is larger than that of the gate 120. In the embodiment of this present invention, the height ratio of the gate 110 to the gate 120 is in the ranges of 1.1˜2.0, prefer to in the ranges of 1.4˜1.8. Furthermore, the step of removing the exposed portion of the gates 110, 120 may be omitted due to the adjusting of the annealing process conditions.

Next, a metal layer 134 is formed on the substrate 100. The metal layer 134 contacts the gates 110, 120. The material of the metal layer 134 is, for example, selected from a group consisting of Ni, Co, Ti, Cu, Mo, Ta, W, Er, Zr, Pt, Yb, Gd, Dy and the alloy thereof. The method of forming the metal layer 134 includes evaporation, sputtering, electroplating, CVD, or PVD. In the present invention, the materials of the metal layer 134 and the metal layer 128 can be the same or different. The silicidation reaction temperature of the metal layer 134 is preferably lower than that of the metal layer 128. As the silicidation reaction temperature of Ni is lower than that of Co, in the following description, the material of the metal layer 134 is, for example, Ni.

Referring to FIG. 1D, an annealing process is performed such that the silicon in the gates 110, 120 is reacted with the metal layer 134 to form silicided gates 110a, 120a. During the annealing process, the metal layer 134 and the silicon layer adjacent to the metal layer 134 assume the inter-diffusion state due to high temperature, and the atoms are rearranged to form the silicide. The silicided gates 110a, 120a include one of the refractory metal, noble metal and rear-earth metal silicide, for example, selected from a group of silicides of metals Ni, Co, Ti, Cu, Mo, Ta, W, Er, Zr, Pt, Yb, Gd, Dy and alloys thereof. The material of the gate 110 is undoped polysilicon, and a silicon-rich silicide is formed after the gate 110 is reacted with the metal layer 134. The material of the gate 120 is doped polysilicon, and a metal-rich silicide is formed after the gate 120 is reacted with the metal layer 134.

The temperature of annealing process and the time of annealing vary in accordance with different materials of the metal layer and the gate height. In the present embodiment, the material of the metal layer 134 is, for example, Ni, so the temperature of the annealing process is, for example, 350˜700° C., and the annealing time is about 10600 seconds. Further, the material of the silicided gate 110a includes silicon-rich silicide (with the M/Si composition ratio of M:Si<1.5:1), and the material of the silicided gate 112a includes metal(M)-rich silicide (with the M/Si composition ratio of M:Si>1.5:1). For example, the metal (M) is Ni. The material of the silicided gate 110a is silicon-rich nickel silicide (with the Ni/Si composition ratio of Ni:Si<1.5:1), for example, Ni2Si or NiSi, and the material of the silicided gate 112a is metal(M)-rich nickel silicide (with the Ni/Si composition ratio of Ni:Si>1.5:1), for example, Ni2Si, Ni31Si12 or Ni3Si.

Next, the unreacted metal layer 134 is removed. In the present invention, the so-called unreacted metal layer 134 refers to a part of the metal layer 134 which does not participate in the silicided reaction or is not completely reacted. The method of removing the unreacted metal layer 134 is, for example, a selective wet-etching process. The unreacted metal layer 134 is removed by using a hydrochloric acid/hydrogen peroxide mixed solution or a sulfuric acid/hydrogen peroxide mixed solution as etchant, only leaving the completely silicided gates 110a, 120a. Then a second annealing process may be performed to lower resistance of the silicided gates 110a, 120a. The temperature of the second annealing process and the annealing time are decided according to the material of metal layer.

In the present invention, the so-called silicidation process is constituted of a metal layer forming process, a first annealing process, a process of removing the unreacted metal layer and a second annealing process. With one silicidation process, silicided gates 110a, 120a of different materials and different properties can be formed simultaneously.

Next, a dielectric layer 136 is formed on the substrate 100, and the dielectric layer 136 completely covers the transistor 102 and the transistor 104. The material of the dielectric layer 136 is, for example, silicon nitride, and may be formed by, for example, a CVD process. Thereafter, an interlayer insulating layer 138 is formed on the substrate 100. The material of the interlayer insulating layer 138 is, for example, silicon oxide, phosphor-silicate glass (PSG), boron-phosphor-silicate glass (BPSG), and the like.

In the method of manufacturing the semiconductor device having a dual fully-silicided gate according to the first embodiment of the present invention, the materials of the gates of the transistor 102 and the transistor 104 are different. After removing the cap layers 112, 122 to expose the gates 110, 120, a silicidation process is performed, and thus silicided gates 110a, 120a having different properties are formed. The additional lithographic etching process is not required, thus simplifying the process. Moreover, the cap layers 112, 122 are removed by wet-etching instead of CMP, and the process can be simplified and the cost can be reduced as well.

Moreover, the process temperature during the formation of the source/drain silicided layers 130, 132 is higher than that of the silicided gates 110a, 120a, so when forming the silicided gates 110a, 120a, the silicon in the source/drain 116 and the source/drain 126 can be prevented from further reacting with the metal layer 134 due to the intermediating barrier source/drain silicided layers 130, 132, thereby avoid influencing the device characteristics.

Moreover, the height of the gates 110, 120 can be adjusted by removing the exposed portions of the gates 110, 120, so the silicided gates 110a, 120a subsequently formed can be adjusted, such that the silicided gates 110a, 120a have preferred operation performance and characteristic. In the embodiment of this invention, the height ratio of the silicided gates 110a to 120a, for example, is in the ranges of 0.8˜1.5, prefer to in the ranges of 1.0˜1.3.

Still referring to FIG. 1D, the semiconductor device having a dual fully-silicided gate of the present invention is illustrated.

As shown in FIG. 1D, the semiconductor device having a dual fully-silicided gate of the present invention at least includes a transistor 102 and a transistor 104. The material of the silicided gate 110a of the transistor 102 is different from the material of the silicided gate 120a of the transistor 104. The material of the silicided gate 110a of the transistor 102 includes silicon-rich silicide, for example, NiSi2 and NiSi. The material of the silicided gate 120a of the transistor 104 includes metal-rich silicide, for example, Ni2Si, Ni31Si12 and Ni3Si. The silicided gate 110a and the silicided gate 120a are formed in one silicidation process. The dielectric layer 136 completely covers the transistor 102 and the transistor 104. The interlayer insulating layer 138 is disposed on the dielectric layer 136.

According to an embodiment of the present invention, the silicided gate 110a of the transistor 102 and the silicided gate 120a of the transistor 104 are made of different materials, so that the transistor 102 and the transistor 104 have different operation performance and characteristic. Moreover, the silicided gate 110a of the transistor 102 and the silicided gate 120a of the transistor 104 are formed in one silicidation process, thus simplifying the process and reducing the cost. The less height ratio of silicided gates 110a to 120a also provides the relative large planarity window.

In the above-mentioned embodiment, the transistor 102 and the transistor 104 are, for example, typical transistors. Otherwise, the transistor 102 and the transistor 104 may be FinFETs or Multi-gate transistors.

### The Second Embodiment

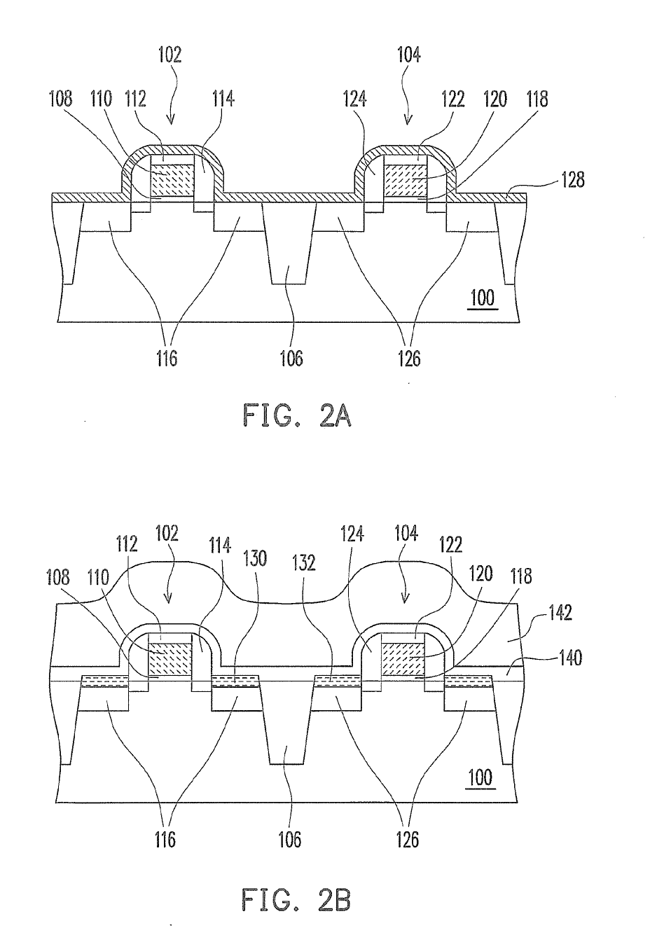

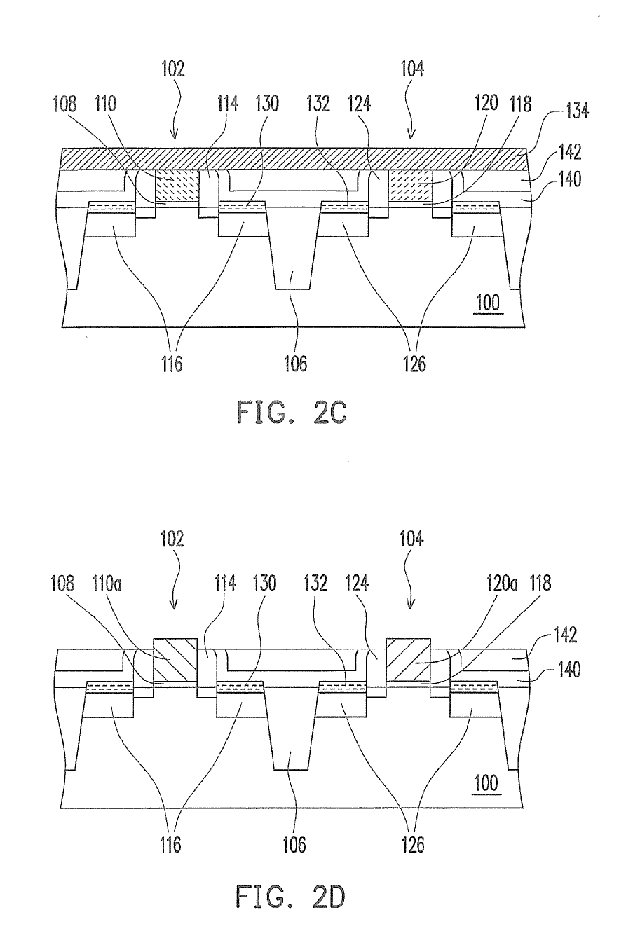

FIG. 2A to FIG. 2D are cross-sectional views of the process steps of the method of manufacturing the semiconductor device having a dual fully-silicided gate according to the second embodiment of the present invention. The second embodiment is a modified process of the first embodiment, and in the second embodiment, the components same as those in the first embodiment are indicated with the same symbols, and the details thereof will not be described herein again.

Referring to FIG. 2A, first a substrate 100 is provided. The substrate 100 includes silicon substrate. A transistor 102 and a transistor 104 are already formed on the substrate 100. The transistor 102 and the transistor 104 are isolated by, for example, device isolation structures 106. The transistor 102 includes, for example, a gate dielectric layer 108, a gate 110, a cap layer 112, spacers 114, and source/drain 116. The transistor 104 includes, for example, a gate dielectric layer 118, a gate 120, a cap layer 122, spacers 124, and source/drain 126. In the following description, the material of the gate 110 is, for example, undoped polysilicon, the transistor 102 is, for example, NMOS, the material of the gate 120 is, for example, doped polysilicon, and the transistor 104 is, for example, PMOS.

Then, a metal layer 128 is formed on the substrate 100. The material of the metal layer 128 includes one of the refractory metal, noble metal, and rear-earth metal for example, selected from a group consisting of Ni, Co, Ti, Cu, Mo, Ta, W, Er, Zr, Pt, Yb, Gd, Dy and alloys thereof. In the embodiment of this present invention, the material of metal layer 128 includes, for example, Co.

Referring to FIG. 2B, a first annealing process is performed such that the silicon in the source/drain 116 and the source/drain 126 is reacted with the metal layer 128 to form silicided layers 130, 132. The silicides 130, 132 include one of the refractory metal, noble metal and rear-earth metal silicide, for example, selected from a group of silicides of metals Ni, Co, Ti, Cu, Mo, Ta, W, Er, Zr, Pt, Yb, Gd, Dy and alloys thereof. Next, the unreacted metal layer 128 is removed and a second annealing process is performed. In the embodiment of this present invention includes, for example, CoSi2.

Next, a material layer 140 is formed on the substrate 100. The material of the material layer 140 is, for example, silicon nitride, and may be formed by, for example, a CVD process. An insulation layer 142 is formed on the material layer 140. The insulation layer 142 is, for example, silicon oxide, phosphor-silicate glass, boron-phosphor-silicate glass, and may be formed by, for example, a CVD process. The material layer 140 and insulation layer 142 are used to protect the silicided layers 130, 132 on the source/drain 116 and the source/drain 126 from being influenced by the subsequent silicidation process.

Referring to FIG. 2C, portions of the material layer 140, the insulation layer 142 and the cap layers 112, 122 are removed to expose the gates 110, 120. The portions of the material layer 140, insulation layer 142 and cap layers 112, 122 may be removed by, for example, performing CMP process, etching process and their combination. The removal could also be proceeded as to remove portions of the material layer 140 and insulation layer 142 by CMP followed by removing the cap layer 112, 122 by etching process with high selectivity to materials layer 140 and insulation layer 142. The residual material layer 140 and the residual insulation layer 142 at least cover the silicided layers 130, 132 on the source/drain 116 and the source/drain 126. During the process of removing a part of the material layer 140, the insulation layer 142 and cap layers 112, 122, a portion of the spacers 114, 124 is also removed.

Next, a metal layer 134 is formed on the substrate 100. The metal layer 134 contacts the gates 110, 120. The material of the metal layer 134 is, for example, selected from a group consisting of Ni, Co, Ti, Cu, Mo, Ta, W, Er, Zr, Pt, Tb, Gd, Dy and alloy thereof. In the present invention, the material of the metal layer 134 and the material of the metal layer 128 can be the same or different. In the embodiment of this invention, material of the metal layer 134 is includes, for example, Ni. As the material layer 140 and the insulation layer 142 are used to protect the silicided layers 130, 132 on the source/drain 116 and the source/drain 126, the silicidation reaction temperature of the metal layer 134 need not be lower than that of the metal layer 128. Alternatively, before forming the metal layer 134, the exposed portion of the gates 110, 120 may also be removed to adjust the height of the gates 110, 120. In the embodiment of this present invention, the height ratio of the gate 110 to the gate 120 is in the ranges of 1.1˜2.0, prefer to in the ranges of 1.4˜1.8.

Referring to FIG. 2D, an annealing process is performed such that the silicon in the gates 110, 120 is reacted with the metal layer 134 to form silicided gates 110a, 120a. The silicided gates 110a, 120a include one of the refractory metal, noble metal and rear-earth metal silicide, for example, selected from a group of silicides of metals Ni, Co, Ti, Cu, Mo, Ta, W, Er, Zr, Pt, Yb, Gd, Dy and alloys thereof. The material of the gate 110 is undoped polysilicon, and a silicon-rich silicide including, for example, NiSi2 and NiSi, is formed after the gate 110 is reacted with the metal layer 134. The material of the gate 120 is doped polysilicon, and a metal-rich silicide including, for example, Ni2Si, Ni31Si12 and Ni3Si, is formed after the gate 120 is reacted with the metal layer 134. Next, the unreacted metal layer 134 is removed and a second annealing process is performed.

In the method of manufacturing the semiconductor device having a dual fully-silicided gate according to the second embodiment of the present invention, the material of the gates of the transistor 102 and the transistor 104 are different. After removing portions of the material layer 140, the insulation layer 142 and cap layers 112, 122 to expose the gates 110, 120, silicided gates 110a, 120a having different properties can be formed by performing a silicidation process. The additional lithographic etching process is not required, thus simplifying the process and saving the cost.

Moreover, as the material layer 140 and the insulation layer 142 are used to protect the silicided layers 130, 132 on the source/drain 116 and the source/drain 126, when form the silicided gates 110a, 120a, the silicon in the source/drain 116 and the source/drain 126 can be prevented from being further reacted with the metal layer 134 due to the protection of the portions of the materials layer 140 and the insulation layer 142, thereby avoid influencing the device characteristics.

In addition, the height of the gates 110, 120 can be adjusted by removing the exposed part of the gates 110, 120, so the silicided gates 110a, 120a subsequently formed can be adjusted, such that the silicided gates 110a, 120a have preferred operation performance and characteristics. In the embodiment of this invention, the height ratio of the silicided gates 110a to 120a, for example, is in the ranges of 0.8˜1.5, prefer to in the ranges of 1.0˜1.3. The insulation layer 142 is formed optionally. In some case, the materials layer 140 is formed independently without insulation layer 142.

In the above-mentioned embodiment, the transistor 102 and the transistor 104 are, for example, typical transistors. Otherwise, the transistor 102 and the transistor 104 may be FinFETs or Multi-gate transistors.

### The Third Embodiment

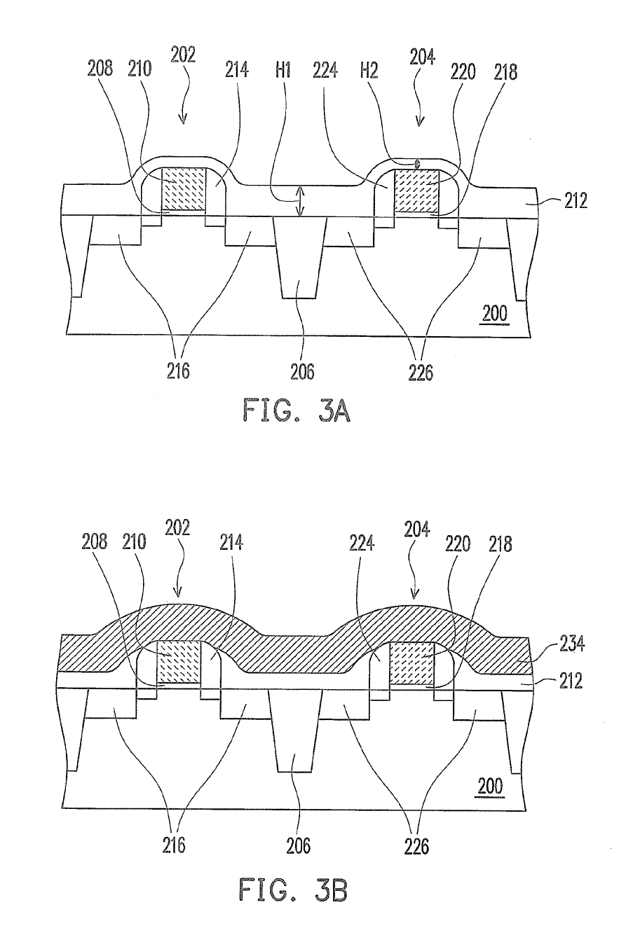

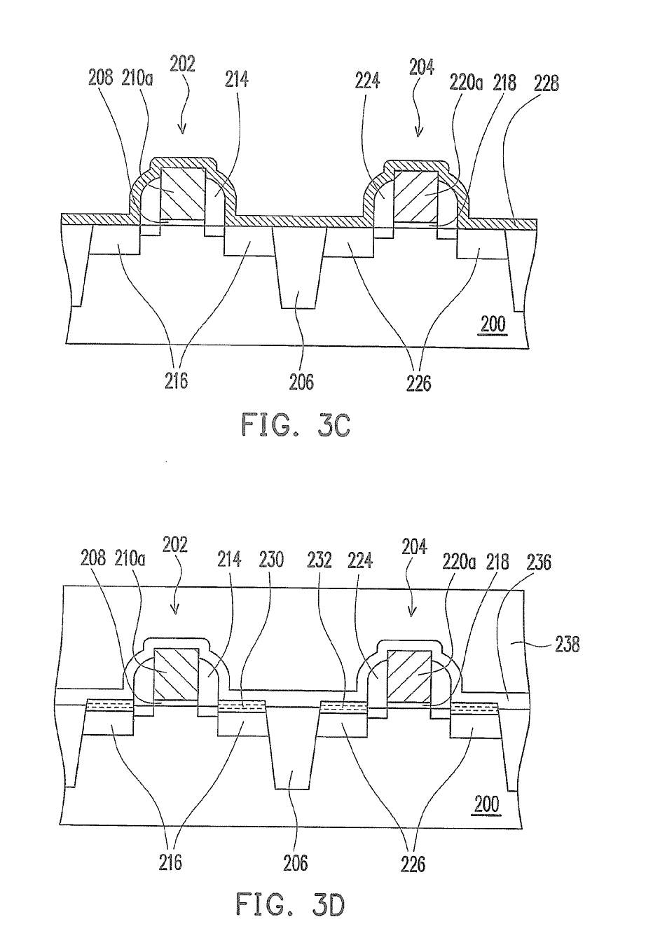

FIG. 3A to FIG. 3D are cross-sectional views of the process steps of the method of manufacturing the semiconductor device having a dual fully-silicided gate according to the third embodiment of the present invention.

Referring to FIG. 3A, first a substrate 200 is provided. The substrate 200 includes silicon substrate, for example, N-type silicon substrate or P-type silicon substrate. The substrate 200 can also be a silicon-on-insulating layer substrate and the like.

A transistor 202 and a transistor 204 are already formed on the substrate 200. The transistor 202 and the transistor 204 are isolated by, for example, device isolation structures 206. The device isolation structure 206 is, for example, a shallow trench isolation structure or a field oxide layer.

The transistor 202 includes, for example, a gate dielectric layer 208, a gate 210, spacers 214, and source/drain 216. The transistor 204 includes, for example, a gate dielectric layer 218, a gate 220, spacers 224, and source/drain 226.

The material of the gate dielectric layers 208, 218 includes a high-K material with a dielectric constant larger than 4, for example, SiO2, SiON, SiN, Ta2O5, Al2O3, HfO2, HfSiON, HfSiO2, and HfAlSiO2. The gate dielectric layers 208, 218 can be formed by one or more dielectric material layers. For example, the gate dielectric layers 208, 218 can be formed by a single layer of the above high-K material, or formed by a silicon oxide layer and a high-K material layer.

The material of the gates 210, 220 is, for example, silicon based material, for example, selected from a group consisting of doped silicon, undoped silicon, doped polysilicon, and undoped polysilicon. When the material of the gates 210, 220 is doped silicon or doped polysilicon, the dopant in the silicon or polysilicon can be N-type dopant or P-type dopant. In the following description, the material of the gate 210 is, for example, undoped polysilicon and the transistor 202 is, for example, NMOS, the material of the gate 220, for example, doped polysilicon, and the transistor 204, for example, PMOS.

Next, a material layer 212 is formed on the substrate 200. The material of the material layer 212 includes, for example, silicon oxide, phosphor-silicate glass, boron-phosphor-silicate glass or carbon-doped low dielectric constant layer, and may be formed by, for example, spin-coating process. The material layer 212 is used to protect the source/drain 216 and the source/drain 226 from being influenced by the subsequent silicidation process. As the material layer 212 is formed by a spin-coating process, the thickness H1 of the material layer 212 on the surface of the substrate 200 is larger than the thickness H2 of the material layer 212 on the surface of the gate 210 and the gate 220.

Referring to FIG. 3B, a part of the material layer 212 is removed to expose the gates 210, 220. The portion of the material layer 212 may be removed by performing an isotropic etching process, for example, wet etching process. The thickness H1 of the material layer 212 on the surface of the substrate 200 is larger than the thickness H2 of the material layer 212 on the surface of the gate 210 and the gate 220, so a portion of the material layer 212 on the surface of the substrate 200 is left covering at least the source/drain 216 and the source/drain 226.

Next, a metal layer 234 is formed on the substrate 200, and the metal layer 234 contacts the gate 210 and the gate 220. The material of the metal layer 234 includes, for example, selected form a group consisting of Ni, Co, Ti, Cu, Mo, Ta, W, Er, Zr, Pt, Yb, Gd, Dy and alloys thereof. In the embodiment of this present invention, the material of metal layer 234 includes, for example, Ni. The process of forming the metal layer 234 includes evaporation, sputtering, electroplating, CVD, or PVD process. Alternatively, before forming the metal layer 234, the exposed portion of the gates 210, 220 can be removed to adjust the height of the gates 210, 220. In the embodiment of this present invention, the height ratio of the gate 210 to the gate 220 is in the ranges of 1.1˜2.0, prefer to in the ranges of 1.4˜1.8.

Referring to FIG. 3C, a first annealing process is performed such that the silicon in the gates 210, 220 is reacted with the metal layer 234 to form silicided gates 210a, 220a. In the embodiment of this present invention, the annealing temperature is in the ranges of 400˜700 C. The annealing time is in the ranges of 10˜600 sec. During the first annealing process, the metal layer 234 and the silicon layer adjacent to the metal layer 234 assume the inter-diffusion states due to high temperature, and the atoms are rearranged to form silicides gates 210a, 220a. The silicided gates 210a, 220a include one of the refractory metal, noble metal and rear-earth metal silicide, for example, selected from a group of silicides of metals Ni, Co, Ti, Cu, Mo, Ta, W, Er, Zr, Pt, Yb, Gd, Dy and alloys thereof. The material of the gate 210 is undoped polysilicon, and a silicon-rich silicide is formed after the gate 210 is reacted with the metal layer 234. In the embodiment of this present invention, the material of silicon-rich silicide includes, for example, NiSi2 and NiSi. The material of the gate 220 is doped polysilicon, and a metal-rich silicide is formed after the gate 220 is reacted with the metal layer 234. In the embodiment of this present invention, the material of metal-rich silicide includes, for example, Ni2Si, Ni31Si12 and Ni3Si.

Next, the unreacted metal layer 234 is removed. The process of removing the unreacted metal layer 234 includes, for example, a selective wet-etching process using a hydrochloric acid/hydrogen peroxide mixed solution or a sulfuric acid/hydrogen peroxide mixed solution as etchant.

Next, the residual material layer 212 is removed to expose the source/drain 216 and the source/drain 226. The residual material layer 212 may be removed by performing, for example, an isotropic etching process, for example, wet etching process.

Next, a metal layer 228 is formed on the substrate 200. The material of the metal layer 228 includes refractory metal, for example, selected from a group consisting of Ni, Co, Ti, Cu, Mo, Ta, W, Er, Zr, Pt, Yb, Gd, Dy and alloys thereof. In the embodiment of this present invention, the material of metal layer 228 includes, for example, Ni or Co. The method of forming the metal layer 228 includes evaporation, sputtering, electroplating, CVD, or PVD process.

Referring to FIG. 3D, a first annealing process is performed such that the silicon in the source/drain 216 and the source/drain 226 is reacted with the metal layer 228 to form silicided layers 230, 232. The material of the silicided layers 230, 232 includes one of the refractory metal, noble metal and rear-earth metal silicide, for example, selected from a group of silicides of metals Ni, Co, Ti, Cu, Mo, Ta, W, Er, Zr, Pt, Yb, Gd, Dy and alloys thereof. In the embodiment of this present invention, the material of the silicided layers 230, 232 includes, for example, NiSi or CoSi2.

Next, the unreacted metal layer 228 is removed. The process of removing the unreacted metal layer 228 includes, for example, a selective wet-etching process. The unreacted metal layer 228 is removed by using a hydrochloric acid/hydrogen peroxide mixed solution or a sulfuric acid/hydrogen peroxide mixed solution as etchant, only leaving the silicided layers 230, 232 on the surface of the source/drain 216 and the source/drain 226. Then a second annealing process is performed.

Next, a dielectric layer 236 is formed on the substrate 200, and the dielectric layer 236 completely covers the transistor 202 and the transistor 204. The material of the dielectric layer 236 is, for example, silicon nitride, and may be formed by performing, for example, a CVD process. Thereafter, an interlayer insulating layer 238 is formed on the substrate 200. The material of the interlayer insulating layer 238 is, for example, silicon oxide, phosphor-silicate glass, boron-phosphor-silicate glass, and the like.

In the method of manufacturing the semiconductor device having a dual fully-silicided gate according to the third embodiment of the present invention, the materials of the gates of the transistor 202 and the transistor 204 are different. After removing the material layer 212 to expose the gates 210, 220, a silicidation process is performed, and thus the silicided gates 210a, 220a having different properties are formed. The additional lithographic etching process is not required, thus simplifying the process. Moreover, the material layer 212 is removed by wet-etching instead of CMP, thus simplifying the process and reducing the cost.

Moreover, the material layer 212 is used to protect the source/drain 216 and the source/drain 226, so when forming the silicided gates 210a, 220a, the metal layer 234 can be prevented from reacting with the silicon in the source/drain 216 and the source/drain 226.

In addition, the height of the gates 210, 220 can be adjusted by removing the exposed portions of the gates 210, 220, so silicided gates 210a, 220a subsequently formed can be adjusted, such that the silicided gates 210a, 220a have preferred operation performance and characteristics. In the embodiment of this invention, the height ratio of the silicided gates 210a to 220a, for example, is in the ranges of 0.8˜1.5, prefer to in the ranges of 1.0˜1.3.

In the above-mentioned embodiment, the transistor 102 and the transistor 104 are, for example, typical transistors. Otherwise, the transistor 102 and the transistor 104 may be FinFETs or Multi-gate transistors.

To sum up, in the method of manufacturing the semiconductor device having a dual fully-silicided gate of the present invention, silicided gates having different properties can be formed by only one silicidation process. The additional lithographic etching process is not required, thus simplifying the process and saving the cost.

Furthermore, the same metal for the gate silicide and source/drain silicide, the process temperature of the silicided layer formed on the gates is higher than that of the silicided source/drain, so when forming the silicided gates prior to source/drain, the source/drain silicide can be prevented from over reacting with the silicon in the source/drain due to the higher annealing temperature while forming silicided gates, thereby avoid influencing the device characteristics.

Moreover, the height of the gates can be adjusted by removing the exposed portions of the gates, so the subsequently formed silicided gates can be adjusted, such that the silicided gates have preferred operation performance and characteristics.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of manufacturing the semiconductor device having a dual fully-silicided gate, comprising:
providing a substrate having a first transistor and a second transistor formed thereon, the first transistor comprising a first gate and a first source/drain, and the second transistor comprising a second gate and a second source/drain, wherein the gate height of the first gate is different from that of the second gate; and
performing a first silicidation process to respectively transform the first gate and the second gate into a first silicided gate and a second silicided gate simultaneously, wherein the material of the first silicided gate is different from that of the second silicided gate.

2. The method of manufacturing the semiconductor device having a dual fully-silicided gate as claimed in claim 1, wherein the first gate comprises undoped polysilicon, and the second gate comprises doped polysilicon.

3. The method of manufacturing the semiconductor device having a dual fully-silicided gate as claimed in claim 1, wherein the gate height ratio of the first gate and the second gate is 1.4˜1.8.

4. The method of manufacturing the semiconductor device having a dual fully-silicided gate as claimed in claim 1, wherein the first silicided gate comprises silicon-rich silicide, and the second silicided gate comprises metal-rich silicide.

5. The method of manufacturing the semiconductor device having a dual fully-silicided gate as claimed in claim 4, wherein the gate silicide height ratio of the first gate silicide and the second gate silicide is 0.8˜1.5.

6. The method of manufacturing the semiconductor device having a dual fully-silicided gate as claimed in claim 4, wherein the gate silicide height ratio of the first gate silicide and the second gate silicide is 1.0˜1.3.

7. The method of manufacturing the semiconductor device having a dual fully-silicided gate as claimed in claim 1, wherein the first silicided gate and the second silicided gate comprise refractory metal silicide, noble metal silicide or rear-earth metal silicide.

8. The method of manufacturing the semiconductor device having a dual fully-silicided gate as claimed in claim 1, wherein the first silicidation process comprises:
forming a first metal layer on the substrate, wherein the first metal layer contacts the first gate and the second gate; and
performing a first annealing process such that the first metal layer is reacted with the first gate and the second gate to form a silicide;
removing any unreacted first metal layer; and
performing a second annealing process to form a lower resistance silicide.

9. The method of manufacturing the semiconductor device having a dual fully-silicided gate as claimed in claim 8, wherein a material of the first metal layer is selected from a group consisting of Ni, Co, Ti, Cu, Mo, Ta, W, Er, Zr, Pt, Yb, Gd, Dy and alloys thereof.

10. The method of manufacturing the semiconductor device having a dual fully-silicided gate as claimed in claim 1, wherein the first silicided gate comprises silicon-rich NiSi with the Ni/Si composition ratio of Ni:Si<1.5:1; and the second silicided gate comprises nickel-rich NiSi with the Ni/Si composition ratio of Ni:Si>1.5:1.

11. The method of manufacturing the semiconductor device having a dual fully-silicided gate as claimed in claim 10, wherein the silicon-rich silicided gate comprises NiSi2 or NiSi.

12. The method of manufacturing the semiconductor device having a dual fully-silicided gate as claimed in claim 10, wherein the nickel-rich silicided gate comprises Ni2Si, Ni31Si12 and Ni3Si.

13. The method of manufacturing the semiconductor device having a dual fully-silicided gate as claimed in claim 1, further comprising a step of forming a material layer on the substrate and a step of removing a part of the material layer to expose the first gate and the second gate only before the step of performing the first silicidation process.

14. The method of manufacturing the semiconductor device having a dual fully-silicided gate as claimed in claim 13, wherein the material layer comprises a spin-coating material layer.

15. The method of manufacturing the semiconductor device having a dual fully-silicided gate as claimed in claim 13, further comprising a step of removing the residual material layer and a step of performing a second silicidation process to form a silicided layer on the first source/drain and the second source/drain after the step of performing the first silicidation process.

16. The method of manufacturing the semiconductor device having a dual fully-silicided gate as claimed in claim 15, wherein the second silicidation process comprises:
forming a second metal layer on the substrate, wherein the second metal layer contacts the first source/drain and the second source/drain;
performing a first annealing process such that the second metal layer is reacted with the first source/drain and the second source/drain to form a silicide;
removing any unreacted second metal layer; and
performing a second annealing process to form a lower resistance silicide.

17. The method of manufacturing the semiconductor device having a dual fully-silicided gate as claimed in claim 16, wherein a material of the second metal layer is selected from a group consisting of Ni, Co, Ti, Cu, Mo, Ta, W, Er, Zr, Pt, Yb, Gd, Dy and alloys thereof.

18. The method of manufacturing the semiconductor device having a dual fully-silicided gate as claimed in claim 15, wherein a process temperature of the second silicided layer is lower than that of the first silicided gate and the second silicided gate.

19. The method of manufacturing the semiconductor device having a dual fully-silicided gate as claimed in claim 15, wherein a material of the second silicided layer is NiSi.

20. The method of manufacturing the semiconductor device having a dual fully-silicided gate as claimed in claim 1, further comprising:
forming a first gate dielectric layer between the first gate and the substrate; and
forming a second gate dielectric layer between the second gate and the substrate.

21. The method of manufacturing the semiconductor device having a dual fully-silicided gate as claimed in claim 20, wherein the first gate dielectric layer and the second gate dielectric layer are formed by one or more dielectric material layers.

22. The method of manufacturing the semiconductor device having a dual fully-silicided gate as claimed in claim 20, wherein the first gate dielectric layer and the second gate dielectric layer comprise a high-K material with a dielectric constant larger than 4.

23. The method of manufacturing the semiconductor device having a dual fully-silicided gate as claimed in claim 20, wherein a material of the first gate dielectric layer and the second gate dielectric layer is selected from a group consisting of SiO2, SiON, SiN, Ta2O5, Al2O3, HfO2, HfSiON, HfSiO2, and HfAlSiO2.

24. The method of manufacturing semiconductor device having a dual fully-silicided gate as claimed in claim 1, wherein the first transistor and the second transistor are FinFETs.

25. The method of manufacturing semiconductor device having a dual fully-silicided gate as claimed in claim 1, wherein the first transistor and the second transistor are Multi-gate transistors.

26. A method of manufacturing the semiconductor device having a dual fully-silicided gate, comprising:
providing a substrate having a first transistor and a second transistor formed thereon, the first transistor comprising a first gate, a first cap layer, and a first source/drain, the second transistor comprising a second gate, a second cap layer and a second source/drain, wherein the gate height of the first gate is different from that of the second gate; and
performing a first silicidation process to form a silicided layer on the first source/drain and the second source/drain;
removing the first cap layer and the second cap layer; and
performing a second silicidation process to respectively transform the first gate and the second gate into a first silicided gate and a second silicided gate simultaneously, wherein the material of the first silicided gate is different from that of the second silicided gate.

27. The method of manufacturing the semiconductor device having a dual fully-silicided gate as claimed in claim 26, wherein the first silicidation process comprises:
forming a first metal layer on the substrate, the first metal layer contacting the first source/drain and the second source/drain; and
performing a first annealing process, such that the first metal layer is reacted with the first source/drain and the second source/drain to form a silicide;
removing any unreacted first metal layer; and
performing a second annealing process to form a lower resistance silicide.

28. The method of manufacturing the semiconductor device having a dual fully-silicided gate as claimed in claim 27, wherein a material of the first metal layer is selected from a group consisting of Ni, Co, Ti, Cu, Mo, Ta, W, Er, Zr, Pt, Yb, Gd, Dy and alloys thereof.

29. The method of manufacturing the semiconductor device having a dual fully-silicided gate as claimed in claim 26, wherein the first gate comprises undoped polysilicon, and the second gate comprises doped polysilicon.

30. The method of manufacturing the semiconductor device having a dual fully-silicided gate as claimed in claim 29, wherein the gate height ratio of the first gate and the second gate is 1.4˜1.8.

31. The method of manufacturing the semiconductor device having a dual fully-silicided gate as claimed in claim 26, wherein the first silicided gate comprises silicon-rich silicide, and the second silicided gate comprises metal-rich silicide.

32. The method of manufacturing the semiconductor device having a dual fully-silicided gate as claimed in claim 26, wherein the second silicidation process comprises:
forming a second metal layer on the substrate, wherein the second metal layer contacts the first gate and the second gate; and
performing a first annealing process such that the second metal layer is reacted with the first gate and the second gate to form a silicide; and
removing any unreacted second metal layer,
performing a second annealing process to form a lower resistance silicide.

33. The method of manufacturing the semiconductor device having a dual fully-silicided gate as claimed in claim 32, wherein a material of the second metal layer is one selected from a group consisting of Ni, Co, Ti, Cu, Mo, Ta, W, Er, Zr, Pt, Yb, Gd, Dy and alloys thereof.

34. The method of manufacturing the semiconductor device having a dual fully-silicided gate as claimed in claim 26, wherein the first silicided gate comprises silicon-rich NiSi with the Ni/Si composition ratio of Ni:Si<1.5:1) and the second silicided gate comprises nickel-rich NiSi with the Ni/Si composition ratio of Ni:Si>1.5:1.

35. The method of manufacturing the semiconductor device having a dual fully-silicided gate as claimed in claim 34, wherein the silicon-rich silicided gate comprises NiSi2 or NiSi.

36. The method of manufacturing the semiconductor device having a dual fully-silicided gate as claimed in claim 34, wherein the nickel-rich silicided gate comprises Ni2Si, Ni31Si12 or Ni3Si.

37. The method of manufacturing the semiconductor device having a dual fully-silicided gate as claimed in claim 26, wherein the step of removing the first cap layer and the second cap layer comprises an etching process.

38. The method of manufacturing the semiconductor device having a dual fully-silicided gate as claimed in claim 26, further comprising a step of removing a portion of the first gate or a portion of the second gate after the step of removing portions of the first cap layer and the second cap layer.

39. The method of manufacturing the semiconductor device having a dual fully-silicided gate as claimed in claim 26, wherein a process temperature of the silicided layer is higher than that of the first silicided gate and the second silicided gate.

40. The method of manufacturing the semiconductor device having a dual fully-silicided gate as claimed in claim 26, further comprising a step of forming a material layer on the substrate and a step of removing portions of the material layer, the first cap layer and the second cap layer until the first gate and the second gate are exposed after the step of performing the first silicidation process.

41. The method of manufacturing the semiconductor device having a dual fully-silicided gate as claimed in claim 40, further comprising a step of removing a portion of the first gate or a portion of the second gate after the step of removing portions of the material layer, the first cap layer and the second cap layer.

42. The method of manufacturing the semiconductor device having a dual fully-silicided gate as claimed in claim 41, wherein a process of removing portions of the material layer, the first cap layer and the second cap layer comprise chemical mechanical polishing (CMP) process or etching process.

43. The method of manufacturing the semiconductor device having a dual fully-silicided gate as claimed in claim 26, further comprising a step of forming a material layer and a insulation layer on the substrate and a step of removing portions of the material layer, the first cap layer and the second cap layer until the first gate and the second gate are exposed after the step of performing the first silicidation process.

44. The method of manufacturing the semiconductor device having a dual fully-silicided gate as claimed in claim 43, further comprising a step of removing a portion of the first gate or a portion of the second gate after the step of removing portions of the insulation layer, the material layer, the first cap layer and the second cap layer.

45. The method of manufacturing the semiconductor device having a dual fully-silicided gate as claimed in claim 44, wherein a process of removing portions of the insulation layer, the material layer, the first cap layer and the second cap layer comprise chemical mechanical polishing (CMP) process or etching process.

46. The method of manufacturing the semiconductor device having a dual fully-silicided gate as claimed in claim 26, wherein the first transistor comprises an NMOS transistor or a PMOS transistor and the second transistor comprises an NMOS transistor or a PMOS transistor.

47. The method of manufacturing the semiconductor device having a dual fully-silicided gate as claimed in claim 26, wherein a first gate dielectric layer is formed between the first gate and the substrate and a second gate dielectric layer is formed between the second gate and the substrate.

48. The method of manufacturing the semiconductor device having a dual fully-silicided gate as claimed in claim 47, wherein the first gate dielectric layer and the second gate dielectric layer are formed by one or more dielectric material layers.

49. The method of manufacturing the semiconductor device having a dual fully-silicided gate as claimed in claim 47, wherein the first gate dielectric layer and the second gate dielectric layer comprise a high-K material with a dielectric constant larger than 4.

50. The method of manufacturing the semiconductor device having a dual fully-silicided gate as claimed in claim 47, wherein a material of the first gate dielectric layer and the second gate dielectric layer is selected form a group consisting of SiO2, SiON, SiN, Ta2O5, Al2O3, HfO2, HfSiON, HfSiO2, and HfAlSiO2.

51. The method of manufacturing semiconductor device having a dual fully-silicided gate as claimed in claim 26, wherein the first transistor and the second transistor are FinFETs.

52. The method of manufacturing semiconductor device having a dual fully-silicided gate as claimed in claim 26, wherein the first transistor and the second transistor are Multi-gate transistors.
